(19) United States
(12) Patent Application Publication
(10) Pub. No.: US 2001/0050995 A1
(43) Pub. Date: Dec. 13, 2001

(54) Audio system

(76) Inventors: Harm Jan Willem Belt, Eindhoven (NL); David Antoine Christian Marie Roovers, Eindhoven (NL)

Correspondence Address: Corporate Patent Counsel, U.S. Philips Corporation, 580 White Plains Road, Tarrytown, NY, 10591, US

(21) Appl. No.: 09/841,962

(22) Filed: Apr. 25, 2001

(30) Foreign Application Priority Data
Apr. 28, 2000 (EP) 00201529.5

(51) Int. Cl. H03G 5/00; H04R 29/00

(52) U.S. Cl. 381/98; 381/60

(57) ABSTRACT

Audio reproduction systems are used to reproduce audio signals. A disadvantage of known audio reproduction systems is that in most cases with stereo or multichannel signals the quality performance of reproduction is very much dependent on the listening position.

The invention proposes a solution by making it possible for the audio reproduction system to localize the position of the listener and amend the reproduced audio signal in dependence of the location.

The invention relates to an audio reproduction system as described in the preamble of claim 1.

The invention further relates to audio processing means for use in such an audio reproduction system.

The invention further relates to a voice controlled system comprising such an audio reproduction system.

The invention further relates to a video reproduction system comprising such an audio reproduction system.

A disadvantage of known audio reproduction systems with stereo or multichannel audio signals is the fact that the audio quality is strongly dependent on the position of the listener in relation to the loudspeakers. When this position differs from the “ideal” position, the reproduction quality is deteriorated to a great extent. This is caused by unwanted amplitude and phase differences between the acoustic transfer functions of the different loudspeakers to the listener.

A further disadvantage is that also in case the listener has taken a position which is geometrically the “ideal” position the acoustic of the room can cause local amplitude and phase differences between the acoustic transfer functions resulting in a deteriorated reproduction.

It is inter alia an object of the invention to obtain an improved audio reproduction system.

To achieve these object(s) an audio reproduction system according to the invention comprises the features of claim 1.

By using at least two microphones it is possible to determine the location of the listener, or at least certain characteristics thereof, when the listener speaks. These techniques are commonly known as “Blind Identification” If the microphones are located close to the loudspeakers, then also the acoustic transfer functions from the listener to the loudspeakers or characteristics thereof, are obtained. The invention is based on the insight that by obtaining the transfer function from the listener to the loudspeakers also the transfer function from the loudspeaker to the listener can be obtained using the reciprocity theorem. Hereafter it is possible to amend the audio signal as supplied to the different loudspeakers to optimize the audio quality at the position of the listener by correcting for the identified amplitude and/or phase differences.

It is to be noticed that from the US Patent U.S. Pat. No. 5,386,478 a sound system remote control with an acoustic sensor is known to optimize the sound quality at a particular listening location as sensed by a microphone in a hand-held remote control unit.

A disadvantage of such a sound system is that for audio systems the location of the remote control and the listener's position (especially his ears/head) is not the same.

An embodiment of the invention comprises the features of claim 2. By using the echo cancellation means the, by the microphone(s), received echo signals from the loudspeakers can be cancelled before the speech signal(s) are further processed.

It is further to be noticed here that the not-prepublished international application no. PCT/EP99/08253 (Applicant's reference: PHN 17.163) describes a signal source localization arrangement for use in video conferencing systems. Herein the localization is used to make the videoconference more “real” by steering a camera towards the source.

Further embodiments of the invention are described in the dependent claims.

These and other aspects of the invention will be apparent from and elucidated with reference to the examples described hereinafter. Herein shows

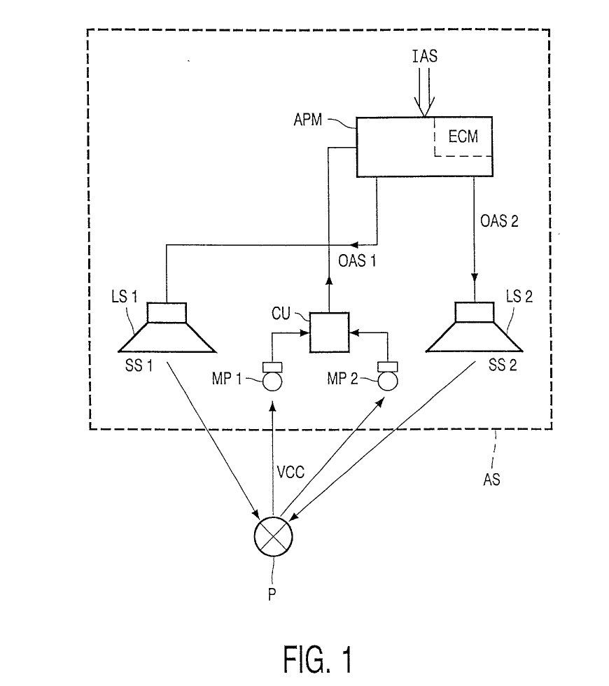

FIG. 1 schematically an example of an audio reproduction system according to the invention, and

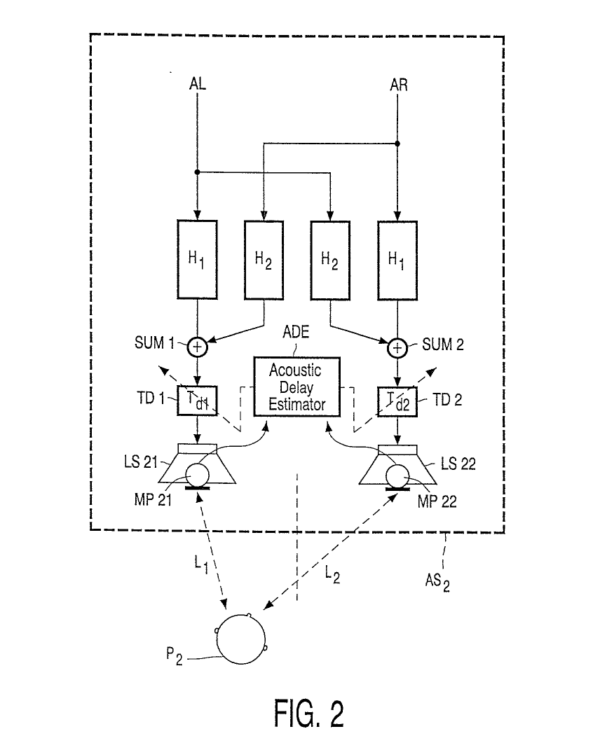

FIG. 2 a second schematically example of an audio reproduction system according to the invention.

FIG. 1 shows an audio reproduction system AS comprising audio processing means APM which audio processing means receive an input audio signal IAS and supply after processing a first output audio signal OAS1 to a first loudspeaker LS1 and a second output audio signal OAS2 to a second loudspeaker LS2. The loudspeakers LS1 and LS2 supply sound signals SS1 and SS2.

The audio reproduction system AS further comprises a first and a second microphone MP1 respectively MP2 for receiving a voice controlled command VCC from a listener P. The first and second microphone MP1, MP2 are coupled to a command unit CU for handling the microphone output signals and supplying a signal to the audio processing means APM.

The audio processing means further comprise echo-cancellation means ECM to cancel the echo signals received with the microphones from the loudspeakers.

The microphones are located in the neighborhood of the respective loudspeakers.

By using at least two microphones it is possible to determine the location of the listener, or at least certain characteristics thereof, when the listener speaks. These techniques are commonly known as “Blind Identification” If the microphones are located close to the loudspeakers, then also the acoustic transfer functions from the listener to the loudspeakers or characteristics thereof, are obtained.

The invention is based on the insight that by obtaining the transfer function from the listener to the loudspeakers also the transfer function from the loudspeaker to the listener can be obtained using the reciprocity theorem.

Hereafter it is possible to amend the audio signal as supplied to the different loudspeakers to optimize the audio quality at the position of the listener by correcting for the identified amplitude and/or phase differences.

By using the echo cancellation means the, by the microphone(s), received echo signals from the loudspeakers can be cancelled before the voice commands are further processed.

In this way it is possible to locate the listener by using e.g. the time difference between the received voice-controlled command at the first respectively second microphone.

FIG. 2 describes in more detail part of the audio reproducing system AS2. This example of a sound reproduction system comprises two closely spaced loudspeakers LS21 and LS22 and two microphones MP21 and MP22. The microphones can be positioned below or above the loudspeaker boxes or they can be integrated into the front panels, or closely in the neighborhood.

The Sound filters H₁ and H₂ operate on the left and right channels (L and R) of the input stereo signal AL and AR, as indicated in FIG. 2. A speaker localization algorithm in the audio reproduction system estimates the difference between the acoustic propagation delays from the user's position to the left and right microphone, respectively. Using the reciprocity theorem, this is also the delay difference between the two acoustic paths from the loudspeakers to the listener, as explained above.

Next, this acoustic propagation time delay is compensated for with a delay T_{d1} in the left channel in a delay device TD2 (if the acoustic path length L₂ between the listener and the right loudspeaker is larger than the acoustic path length L₁ between the listener and the left speaker) or a delay T_{d2} in the right channel with a delay device TD1 (if L₁>L₂).

It is noted that the speaker localization algorithm operates on a narrow band speech signal sampled at e.g. Fₛ=8 kHz, while the Sound filters operate on the full audio bandwidth. The speaker localization is done at low frequencies only, since at frequencies higher than 4 kHz the speech signal contains little power. Also, time delays are ambiguous at higher frequencies due to the short acoustic wavelengths.

The algorithm presented above only works when the music is not playing; with no additional measures the sound emitted by the loudspeakers and picked up by the microphones interferes with the user's speech, leading to incorrect speaker localization. To enable adaptation when the music is playing, two stereo echo cancellers (depicted in FIG. 1 by ECM) can be used in order to cancel the music signals picked up by the two microphones. In this way, the speaker localization algorithm is not affected by the music. With only one stereo echo canceller operating on one microphone it would be possible to detect a speech command, after which the music can be stopped and the speaker localization can be performed before the music starts playing again.

The speaker localization algorithm can be combined with a speech detector so that adaptation is halted during non-speech periods.

With a speech detector the robustness against background noise is increased.

Above the acoustic speaker localization was combined with the so-called Incredible Sound scheme.

However, combinations with any other type of sound processing (other stereo base wideners or normal stereo) are possible.

Until now Incredible Sound could only be heart at full merits only on one position.

With this invention the applicability of Incredible Sound is greatly increased since the listener is no longer restricted to a certain position. The invention can also be seen as a first step towards voice controlled electronic consumer products, which would be acceptable for the greater public.

Applications of the invention can be found in stereo and multi-channel sound reproduction systems such as televisions, in portable stereo sets, and in others.

Above two examples of an audio reproduction system according to the invention are described wherein the speech signals are also used for voice control.

It will be understand by the man skilled in the art that also in cases where no voice controlled operation of the audio reproduction system is available the invention can be used to advantage. The only need is for each loudspeaker a microphone in the neighborhood of the loudspeaker to receive a speech signal from the listener and the audio processing means will amend the audio signal to improve the reproduced audio signal at the location of the listener.

Further it will be noticed that using this audio reproduction system in a video reproduction system is also possible to improve the sound when viewing the pictures on a screen.

1. Audio reproduction system comprising audio processing means for processing an input audio signal, at least two loudspeakers to reproduce the processed audio signal, characterized in that the audio reproduction system comprises means to obtain characteristics of the transfer functions from the loudspeakers to the listener, which means comprise for each loudspeaker a microphone, whereby the microphones are located at least in the neighborhood of the loudspeakers, and the audio processing means comprise means to amend the audio signal in dependence of the location of the listener.

2. Voice-operated audio and/or video reproducing system as claimed in claim 1, characterized in that the audio processing means comprise echo-cancellation means for canceling the echo signals received by the microphones.

3. Audio processing means for use in audio and/or video reproduction system as claimed in claim 1.

4. Voice controlled system comprising an audio reproduction system according to claim 1.

5. Video reproduction system comprising an audio reproduction system according to claim 1.
